(19) United States
(12) Patent Application Publication
(10) Pub. No.: US 2023/0072032 A1
(43) Pub. Date: Mar. 9, 2023

(54) ARITHMETIC UNIT FOR APPROXIMATE CALCULATIONS IN NEURAL NETWORKS

(71) Applicant: Robert Bosch GmbH, Stuttgart (DE)

(72) Inventors: Taha Soliman, Renningen (DE); Andre Guntoro, Weil Der Stadt (DE); Cecilia Eugenia De La Parra Aparicio, Herrenberg (DE)

(21) Appl. No.: 17/798,155

(22) PCT Filed: May 10, 2021
(86) PCT No.: PCT/EP2021/062265

§ 371 Date: Aug. 8, 2022

(30) Foreign Application Priority Data
May 26, 2020 (DE) 10 2020 206 570.5

(51) Int. Cl. G06F 7/523; G06F 7/501; H03K 19/20

(52) U.S. Cl. CPC G06F 7/523; G06F 7/501; H03K 19/20

(57) ABSTRACT

An arithmetic unit for calculating an approximate value for a product or a sum of two inputted numbers. The arithmetic unit includes arithmetic modules, at least one of the arithmetic modules being provided to calculate individual products or individual sums of digits of the inputted numbers, and the arithmetic modules being connected in an adder that is designed to calculate digits of the product or of the sum from the individual products or from the individual sums. An arithmetic module that is required for the calculation of at least one individual product or individual sum, and/or is required for the propagation of this individual product or this individual sum onto the product or the sum, being absent in the arithmetic unit or being connected there in such a way that it is capable of being selectively deactivated, completely or partially, for the running time of the arithmetic unit.

### FIELD

The present invention relates to an arithmetic unit that in particular is capable of performing calculations of weighted sums of inputs to neurons in neural networks in an energy-efficient manner, and that can easily be miniaturized.

### BACKGROUND INFORMATION

Artificial neural networks (ANNs) are made up of a multiplicity of neurons. For each neuron, during operation of the ANN a sum of the inputs to the neuron is to be calculated, the sum being weighted with weights of this neuron. A large number of multiplications thus take place whose results are to be added (multiply-and-accumulate, MAC). In stationary applications of ANNs, typically graphics cards, GPUs, are used for these calculations.

In mobile applications, in particular in battery-operated portable devices or in vehicles, it is often the case that too little energy and too little space are available for the use of powerful GPUs.

German Patent Application No. DE 10 2017 218 889 A1 describes a lossy compressed storage of the weights, which saves memory space for the weights without noticeable loss of quality in the final result of the calculation.

### SUMMARY

According to the present invention, an arithmetic unit is provided for calculating an approximate value for a product or a sum of two inputted numbers. This arithmetic unit includes a plurality of arithmetic modules.

At least one of these arithmetic modules is provided to calculate individual products or individual sums of digits of the inputted numbers. In addition, a plurality of arithmetic modules are connected in an adder. This adder is designed to calculate digits of the product, or of the sum, from the individual products, or from the individual sums. Here it is not excluded that one and the same arithmetic module may both be used for the calculation of an individual product or an individual sum, and may also be part of the adder.

At least one arithmetic module that is required for the calculation of at least one individual product or individual sum, and/or for the propagation of this individual product or this individual sum onto the product or under the sum, is absent in the arithmetic unit, or is connected there in such a way that it can be completely or partially deactivated for the running time of the arithmetic unit.

If a module is missing or is deactivated for the running time, then a result calculated by the arithmetic unit is necessarily no longer exact. However, it has been recognized that in many cases the resulting imprecision has no effect at all, or has only a weak effect, on the final result supplied by the ANN. Thus, if arithmetic units that are not necessarily required to achieve a correct final result are deactivated for the running time or are omitted from the outset in the creation of the arithmetic unit, energy is saved for the operation of these arithmetic units. As a result, in particular mobile battery-operated devices having embedded systems that use an ANN profit from longer battery life. In addition, heat emission is also reduced, so that the arithmetic unit and an embedded system including this arithmetic unit can be made smaller.

Depending on the type of the calculation and the accuracy of the inputted numbers, within certain limits it can already be predicted ahead of time what degree of imprecision in a multiplication or addition will not yet have an effect on the final result supplied by the ANN. This can be the case in particular if for example the two inputted numbers themselves have different degrees of imprecision. Thus, for example in the stated weighted summing of inputs to a neuron, frequently weights are used that, in the binary representation, are only 4 bits wide, while the inputs are signed 8-bit values. In multiplications of 4-bit values by 8-bit values, it is often generally possible to omit the calculation of one or more of the lowest-valued bits of the result without negatively affecting the overall performance of the ANN.

In addition, as a function of the data currently to be processed and the specific application, there is even more room for calculating multiplications and additions with reduced precision. Thus, for example in image analysis it is frequently not important to distinguish the RAL color tones 9004 “signal black,” 9011 “graphite black,” 9017 “traffic black,” and 9005 “jet black” from one another. In contrast, it is extremely important to reliably distinguish the colors red and green, which lie close to one another in the wavelength spectrum, because in street traffic and railway traffic they have the opposite meanings “stop” and “go.” Thus, when there are reduced requirements of precision due to the situation, it can make sense, alternatively to or also in combination with the complete omission of arithmetic modules, to deactivate one or more arithmetic modules for the running time.

In order to deactivate an arithmetic module or parts thereof for the running time, in particular for example the power supply to this arithmetic module, or to this part, can be interrupted. The arithmetic unit can then for example include a control logic unit for controlling the power supply in this regard. The arithmetic module, or the part thereof, can however for example also be designed such that the energy consumption is essentially a function of whether specific data are supplied to it for processing. For the deactivation, it can then for example be sufficient to stop the data flow to the arithmetic module or part.

The above considerations are independent of the number system in which the inputted numbers are represented. In a particularly advantageous embodiment, however, the arithmetic unit is designed to approximately calculate a product of two binary numbers. At least one arithmetic module is then provided to ascertain at least one individual product of two binary numbers, and includes a logical AND gate, a logical XOR gate, and/or a multiplexer. A logical AND gate outputs the truth value 1 only in the case in which both inputted digits are 1. It thus immediately supplies the result of a multiplication of the two digits. A logical XOR gate can be used to ascertain the sign of the result in the case of a multiplication of two signed binary numbers represented in ones' complement. A multiplexer can be used to successively calculate different individual products of digits of the inputted numbers, and to that extent saves many gates that otherwise would be used only for the calculation of an individual product.

In a further particularly advantageous example embodiment of the present invention, the adder comprises a plurality of full adders as arithmetic modules. A full adder can be used for example to add three individual products of binary digits in one working step. In addition, a full adder can be used to combine a result of such an addition with amounts carried over from the calculation of a previous low-valued binary digit.

The partial deactivation of a full adder can include for example the reducing of its functionality to the functionality of a half adder, which can add only two inputs, instead of three. The third input, which can for example be in particular an amount carried over from the calculation of a previous low-valued digit of the product or of the sum, is then left out of account. The partial deactivation can however also for example include the suppression of the outputting of a carryover of the full adder to further full adders that are responsible for the calculation of higher-valued digits of the products or of the sum.

In a particularly advantageous example embodiment of the present invention, at least one arithmetic module and/or its spatial situation inside the arithmetic unit is thermally designed for a lower working cycle than is the case for at least one other arithmetic module. As mentioned above, this can be a function of the situation and the specific data to be processed, which require accuracy in the calculation of the product, or of the sum, for the purposes of the ANN. It cannot be individually predicted when a lower degree of accuracy will be adequate, and thus whether there is a reasonable opportunity to deactivate at least one arithmetic module for the running time. However, it can be estimated for what portion of the operating time on average a lower degree of accuracy is adequate, and for what portion of the operating time a higher degree of accuracy is required. If for example a specific arithmetic module in the provided application has to be activated on average only for 20% of the operating time, and also a particularly long activation at one time is not expected, then in the realization of the arithmetic module and its situation inside the arithmetic unit it can be assumed that on average the arithmetic module will emit only about 20% of its nominal power loss as heat.

In order to design the arithmetic module for a lower working cycle, in particular for example its constructive size can be scaled down. When there is complete loading, the power loss is a limiting factor on further miniaturization; thus, for example modern CPUs or GPUs emit much more power loss per surface unit of area than does a stove burner. The potential for saving space is correspondingly great if an arithmetic module is on average only subjected to low loads, but still has to be present for particular situations in which particularly high accuracy is required. Alternatively or also in combination with this, the distance between the only partly loaded arithmetic module and other components of the arithmetic unit can be reduced.

The arithmetic unit is specialized for the specific application in that, in the arithmetic unit, particular arithmetic modules that are required for the calculation of a precise result are omitted, and/or in that the arithmetic unit is thermally designed for an only partial loading of arithmetic modules. This is to some extent analogous to an application-specific integrated circuit (ASIC).

As explained above, a low energy consumption, a low thermal emission, and a small constructive size of the arithmetic unit are advantageous in particular in control devices for vehicles.

For such control devices, a maximum power consumption and/or a maximum thermal flow that is to be emitted are frequently specified. In addition, for example in the retrofitting of existing vehicles, it can be required to fit a control device that contains the additional functionality of an ANN precisely into the constructive space in which an older control device not having an ANN was previously planned. In particular in the engine compartment of passenger vehicles, it is frequently the case that almost every cubic centimeter is already planned for, so that no additional space is available for an expanded functionality of the control device.

Therefore, the present invention also relates to a control device for a vehicle. This control device includes a first interface that can be connected to at least one sensor on the vehicle. In addition, the control device includes a second interface that can be connected to at least one actuator of the vehicle. The sensor of the vehicle can in particular for example be designed to record physical measurement data through observation of at least a part of the surrounding environment of the vehicle. The actuator of the vehicle can in particular for example be designed to act on the driving dynamics of the vehicle. The control device can be in particular for example part of a driver assistance system and/or part of a system for the at least partly automated driving of the vehicle in traffic.

In addition, the control device includes an artificial neural network ANN that takes part in the processing of measurement data of the sensor to form control signals for the actuator. At least one arithmetic unit as described above is provided for the calculation of a sum of inputs to at least one neuron in the ANN. The sum to be calculated of the inputs is weighted with weights of the neuron.

The ANN in the control device can be designed in particular for example as a classifier for image data that the sensor of the vehicle has recorded as physical measurement data. The image data can be in particular camera images, video images, radar images, lidar images, thermal images, and/or ultrasonic images.

As explained above, for use in an ANN it can be planned at least partly in advance which arithmetic modules in the arithmetic unit are at least temporarily deactivated for the running time, or else can be omitted from the outset without significantly disturbing the functionality of the ANN.

Therefore, the present invention also relates to a method for producing and/or configuring the arithmetic unit 5 described above for the calculation of a sum of inputs of at least one neuron in an artificial neural network ANN, these inputs being weighted with weights of the neuron.

In the context of this method, a candidate configuration of the arithmetic unit is provided that determines which arithmetic modules are omitted, or are completely or partially deactivated. The ANN is trained on the basis of training data such that during this training the arithmetic unit behaves in a manner corresponding to the candidate configuration. In order not to have to carry out the training with the limited hardware resources of the arithmetic unit, but rather to be able to use faster hardware (such as GPUs) for this purpose, during the training in particular for example a simulational representation of the arithmetic unit can be used instead of the physical arithmetic unit. This in particular facilitates the very fast testing of a multiplicity of possible configurations. The training data used in the training can for example include training inputs and associated training outputs, and the training can then for example be directed to the goal that the ANN on average maps the training inputs onto the training outputs.

The success of the training is ascertained on the basis of test data or validation data. For example, for this purpose it can in turn be ascertained to what extent test inputs, or validation inputs, are mapped onto associated test outputs, or validation outputs. If the ANN is for example operated as a classifier, then the success of the training can for example be summarized in the classification accuracy.

Parameters that characterize the candidate configuration are optimized with regard to at least one specified optimization goal, with the boundary condition that the success of the training fulfills a further specified condition. For this purpose, any suitable strategy can be used. For example, as an initial start arithmetic units that are responsible for the calculation of the lowest-valued digit of the product or of the sum can be deactivated or omitted. If the specified further condition (for example relating to the accuracy) is then further fulfilled, then the arithmetic units that are responsible for the calculation of higher-valued digits of the product or of the sum can be successively deactivated or omitted. This “deforestation” can come to an end when the required accuracy is no longer achieved.

As explained above, the specified optimization goal can include in particular
a minimal number of arithmetic modules present or active in the arithmetic unit, and/or
a minimal energy consumption of the arithmetic unit; and/or
a minimal space requirement of the arithmetic unit on at least one semiconductor substrate.

As explained above, arithmetic modules of the arithmetic unit can also be dynamically deactivated for the running time. The extent to which this is possible without excessively falsifying the result provided by the ANN is a function of the specific input data to be processed.

Therefore, the present invention also relates to a further method for operating an ANN that is implemented with at least one arithmetic unit as described above. In this method, on the basis of specific input data that are provided for processing by the ANN, a configuration of the arithmetic unit is ascertained that determines which arithmetic modules of the arithmetic unit are to be deactivated for the running time. Arithmetic modules of the arithmetic unit are completely or partially deactivated corresponding to this configuration. In this state of the arithmetic unit, the input data are supplied to the ANN for the processing.

The relation between the specific input data on the one hand and the arithmetic modules to be deactivated on the other hand can be deduced in many ways. Thus, for example using an arbitrary metric, on the basis of the input data a measure of the resilience of the ANN to changes in the input data can be ascertained. The configuration of the arithmetic unit can then be ascertained on the basis of this measure of the resilience.

In a further particularly advantageous embodiment, the configuration of the arithmetic unit is retrieved on the basis of the input data from a further artificial neural network ANN. It has been recognized that the relation between the input data and the arithmetic modules to be deactivated is accessible in particular to machine learning.

The training of this further ANN can then start for example beginning from the training data of the ANN for which the arithmetic unit is intended. The training inputs can be immediately further used. The configuration associated with these training inputs, onto which the further ANN should ideally map the training inputs, can then for example be determined using an optimization method. Analogous to the first-described method, for example the configuration is sought that is particularly advantageous with respect to a specified optimization goal, while at the same time the ANN equipped with the arithmetic unit configured in this way is still mapped onto the training outputs with adequate reliability.

The further ANN can thus learn, for the ANN to be used for the ultimate processing of the input data, to use the at least one arithmetic unit to find a data-dependent compromise between maximum accuracy of the end result provided by this ANN on the one hand and an arbitrary further optimization goal (such as energy consumption, constructive size, or heat emission) on the other hand.

The method can in particular be completely or partly computer-implemented. Therefore, the present invention also relates to a computer program having machine-readable instructions that, when they are executed on one or more computers, cause the computer or computers to carry out one of the described methods. In this sense, control devices for vehicles and embedded systems for technical devices that are also capable of executing machine-readable instructions are also to be regarded as computers.

The present invention also relates to a machine-readable data carrier and/or to a download product having the computer program. A download product is a digital product that can be transferred via a data network, i.e. can be downloaded by a user of the data network, that may be offered for example in an online shop for immediate download.

In addition, a computer can be equipped with the computer program, with the machine-readable data carrier, and/or with the download product.

Additional measures that improve the present invention are presented in more detail below, together with the description of the preferred exemplary embodiments of the present invention, on the basis of the figures.

### BRIEF DESCRIPTION OF THE DRAWINGS

FIG. 1 shows an exemplary embodiment of arithmetic unit 1, according to the present invention.

FIG. 2 shows an illustration of a multiplication carried out with arithmetic unit 1, according to the present invention.

FIG. 3 shows a further exemplary embodiment of arithmetic unit 1, according to the present invention.

FIG. 4 shows control device 10 for a vehicle 50 having arithmetic unit 1, according to the present invention.

FIG. 5 shows an exemplary embodiment of method 100 for producing and/or configuring an arithmetic unit 1, according to the present invention.

FIG. 6 shows an exemplary embodiment of method 200 for operating an ANN 13, according to the present invention.

### DETAILED DESCRIPTION OF EXAMPLE EMBODIMENTS

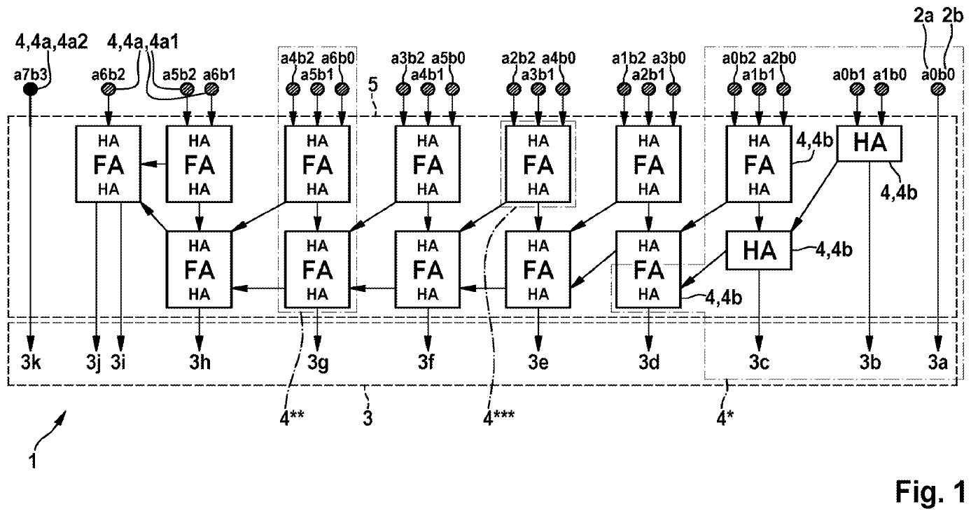

FIG. 1 shows a schematic exemplary embodiment of arithmetic unit 1 that is designed to multiply a signed 8-bit number 2a by a signed 4-bit number 2b. Number 2a includes a lowest-valued digit a0, higher-valued digits a1 through a6, and the sign a7. Number 2b includes a lowest-valued digit b0, higher-valued digits b1 and b2, and the sign b3. Arithmetic unit 1 includes a multiplicity of arithmetic modules 4. These arithmetic modules 4 are subdivided into arithmetic modules 4a, which calculate the individual products of digits of numbers 2a, 2b, and arithmetic modules 4b, which calculate, from these individual products, digits 3a-3k of product 3 of numbers 2a and 2b.

Arithmetic modules 4a are in turn subdivided into AND gate 4a1, as well as an XOR gate 4a2, which by calculation produces sign 3k of product 3 from sign a7 of number 2a and sign b3 of number 2b.

Arithmetic modules 4b include half-adders HA and full adders FA, which are each made up of two half-adders HA.

The example shown in FIG. 1 is based on the determination, obtained from any source, that the three lowest-valued digits 3a-3c of the product 3 of numbers 2a and 2b are not important for the further processing of this product 3. Therefore, arithmetic modules 4a, 4b within marking 4* are deactivated, or are omitted from the outset in arithmetic unit 1. The individual products a0b0, a0b1, a1b0, a0b2, a1b1, and a2b0 are then not even calculated and are not further processed. Digits 3a-3c of product 3 are correspondingly set to zero. A half-adder HA, responsible for the calculation of 3d, which otherwise would have received a carryover from the calculation of digit 3c of product 3, can also be omitted.

In addition, arithmetic modules 4a, 4b inside markings 4** and/or 4*** can also be deactivated for the running time, as a function of the data. Deactivated arithmetic modules 4a, 4b in principle supply only 0 at all outputs. The deactivation saves additional latency time and energy in the running time, at the price that the accuracy of product 3 is worsened compared to the precise value.

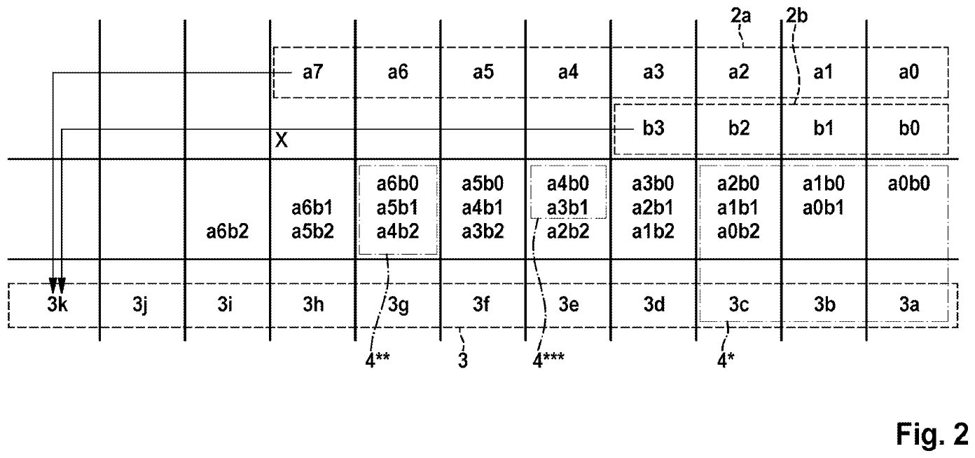

The calculation carried out with arithmetic unit 1 shown in FIG. 1 is illustrated in more detail in FIG. 2. The individual products of digits a0-a6 of number 2a and digits b0-b2 of number 2b are organized in a manner analogous to written multiplication, in such a way that they can be added to yield the digits 3a-3j of product 3. Sign 3k of product 3 is formed from sign a7 of number 2a and sign b3 of number 2b.

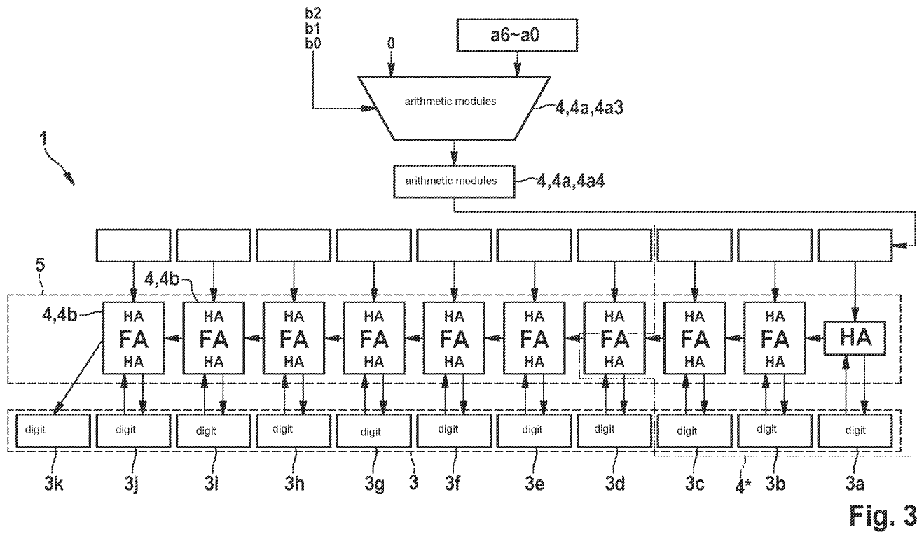

FIG. 3 shows an alternative specific embodiment of arithmetic unit 1. Differing from FIG. 1, instead of AND gate 4a1 there is a multiplexer 4a3 to which digits a0-a6 of number 2a and digits b0-b2 of number 2b are supplied. A register 4a4 controls which arithmetic modules 4b in adder 5 receive the provision in each case of individual products from multiplexer 4a3.

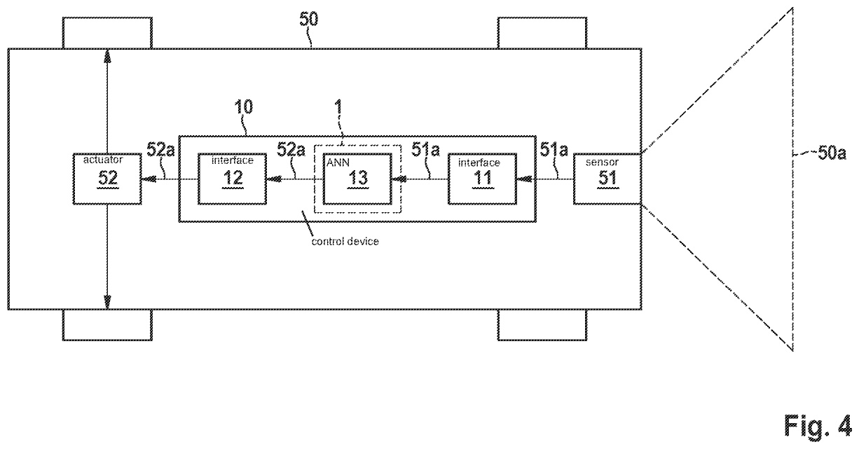

FIG. 4 shows the incorporation of an ANN 13 that uses arithmetic unit 1 in a control device 10 for a vehicle 50.

Interface 11 of control device 10 is connected to sensor 51 of vehicle 50, and receives measurement data 51a that the sensor has recorded through observation of the region of acquisition 50a. Measurement data 51a are processed by ANN 13 using the compact and energy-saving arithmetic unit 1 to form a control signal 52a for an actuator 52 of vehicle 50. Control signal 52a is outputted to actuator 52 of vehicle 50 via interface 12 of control device 50, and causes this actuator 52 to intervene in the driving dynamics of vehicle 50.

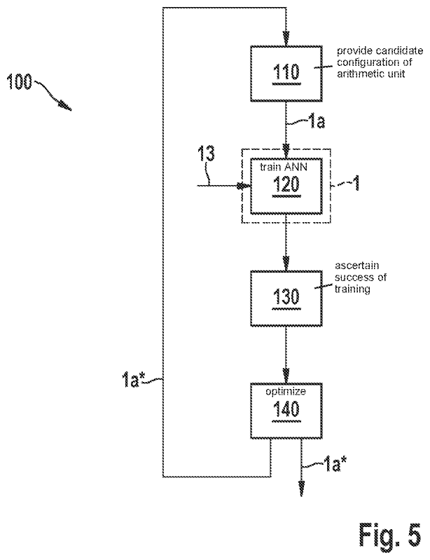

FIG. 5 shows an exemplary embodiment of method 100 for producing and/or configuring an arithmetic unit 1 as described above. In step 110, a candidate configuration 1a of arithmetic unit 1 is provided that determines which arithmetic modules 4, 4a, 4b are absent or are completely or partially deactivated. In step 120, ANN 13 is trained on the basis of training data. Here, arithmetic unit 1, which calculates weighted sums of inputs of at least one neuron in ANN 13, or a simulational representation of this arithmetic unit 1, behaves in a manner corresponding to candidate configuration 1a. The success of training 120 is ascertained in step 130 on the basis of test data, or validation data. Parameters 1a*, which characterize candidate configuration 1a, are thereupon optimized with respect to a specified optimization goal (such as saving space, hardware, or energy), under the boundary condition that the success of the training fulfills a further specified condition. On the basis of the finally trained parameters 1a*, configuration 1a for the arithmetic unit 1 to be used in the specific application can be defined.

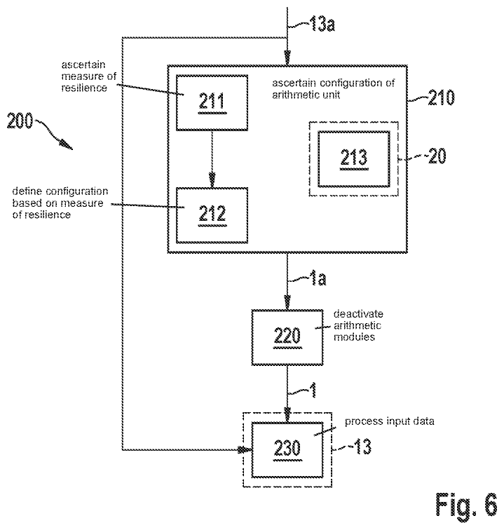

FIG. 6 shows an exemplary embodiment of method 200 for operating the ANN 13. In step 210, a configuration 1a of arithmetic unit 1 is ascertained on the basis of specific input data 13a that are provided for processing by the ANN 13. This configuration 1a indicates which arithmetic modules 4, 4a, 4b of arithmetic unit 1 are to be deactivated for the running time, and when.

Corresponding to this configuration 1a, in step 220 arithmetic modules 4, 4a, 4b of arithmetic unit 1 that is used by ANN 13 are completely or partially deactivated. In this state of arithmetic unit 1, input data 13a are supplied to ANN 13 in step 230 for the processing.

Within box 210, two example possibilities are shown as to how configuration 1a can be ascertained as a function of the data.

According to block 211, a measure of the resilience 13b of ANN 13 against modifications of input data 13a can be ascertained on the basis of input data 13a. According to block 212, configuration 1a can then be defined on the basis of this measure of resilience 13b.

According to block 213, configuration 1a of arithmetic unit 1 can be retrieved from a further ANN 20 on the basis of input data 13a.

1-14. (canceled)

15. An arithmetic unit for calculating an approximate value for a product or a sum of two inputted numbers, comprising:
a plurality of arithmetic modules, at least one of the arithmetic modules being provided to calculate individual products or individual sums of digits of the inputted numbers, the plurality of arithmetic modules being connected in an adder that is configured to calculate digits of the product or of the sum, from the individual products or from the individual sums, at least one arithmetic module that is required for the calculation of at least one individual product or individual sum, and/or is required for the propagation of the individual product or the individual sum onto the product or the sum, being absent in the arithmetic unit or being connected there in such a way that it is capable of being selectively deactivated, completely or partially, for a running time of the arithmetic unit.

16. The arithmetic unit as recited in claim 15, wherein at least one arithmetic module of the arithmetic modules that is provided to calculate at least one individual product of two binary digits including a logical AND gate, and/or logical XOR gate, and/or a multiplexer.

17. The arithmetic unit as recited in claim 16, wherein the adder includes a plurality of full adders as arithmetic modules.

18. The arithmetic unit as recited in claim 15, wherein at least one arithmetic module of the arithmetic modules and/or its spatial situation inside the arithmetic unit, is thermally configured for a lower work cycle than is the case for at least one other of the arithmetic modules.

19. The arithmetic unit as recited in claim 18, wherein at least one arithmetic module of the arithmetic models, or its situation in the arithmetic unit, is configured for a lower work cycle by scaling down its constructive size and/or by reducing a distance between the at least one arithmetic module and other components of the arithmetic unit.

20. A control device for a vehicle, comprising:
a first interface capable of being connected to at least one sensor borne by the vehicle;
a second interface capable of being connected to at least one actuator of the vehicle;
an artificial neural network (ANN) that is involved in processing of measurement data of the sensor to form control signals for the actuator, at least one arithmetic unit being provided for calculation of a sum of inputs of at least one neuron in the ANN, the inputs being weighted with weights of the neuron, the arithmetic unit including:
a plurality of arithmetic modules, at least one of the arithmetic modules being provided to calculate individual products or individual sums of digits of the inputted numbers, the plurality of arithmetic modules being connected in an adder that is configured to calculate digits of the product or of the sum, from the individual products or from the individual sums, at least one arithmetic module that is required for the calculation of at least one individual product or individual sum, and/or is required for the propagation of this individual product or this individual sum onto the product or the sum, being absent in the arithmetic unit or being connected there in such a way that it is capable of being selectively deactivated, completely or partially, for a running time of the arithmetic unit.

21. A method for producing and/or configuring an arithmetic unit for calculation of a sum of inputs of at least one neuron in an artificial neural network (ANN), the inputs being weighted with weights of the neuron, the arithmetic unit including:
a plurality of arithmetic modules, at least one of the arithmetic modules being provided to calculate individual sums of digits of the inputted numbers, the plurality of arithmetic modules being connected in an adder that is configured to calculate digits of the sum, from the individual sums, at least one arithmetic module that is required for the calculation of at least one individual sum, and/or is required for the propagation of the individual sum onto the sum, being absent in the arithmetic unit or being connected there in such a way that it is capable of being selectively deactivated, completely or partially, for a running time of the arithmetic unit,
wherein the method comprises the following steps:
providing a candidate configuration of the arithmetic unit that determines which arithmetic modules are absent or are completely deactivated or partially deactivated;
training the ANN bases on training data, the arithmetic unit, or a simulational representation of the arithmetic unit, behaving in a manner corresponding to the candidate configuration;
ascertaining success of the training based on test data or validation data;
optimizing parameters that characterize the candidate configuration with respect to at least one specified optimization goal, with a boundary condition that the success of the training fulfills a further specified condition.

22. The method as recited in claim 21, wherein the specified optimization goal includes:
a minimal number of arithmetic modules present or activated in the arithmetic unit, and/or
a minimal energy consumption of the arithmetic unit, and/or
a minimal space requirement of the arithmetic unit on at least one semiconductor substrate.

23. A method for operating an artificial neural network (ANN) that is implemented with at least one arithmetic unit including:
a plurality of arithmetic modules, at least one of the arithmetic modules being provided to calculate individual products or individual sums of digits of the inputted numbers, the plurality of arithmetic modules being connected in an adder that is configured to calculate digits of the product or of the sum, from the individual products or from the individual sums, at least one arithmetic module that is required for the calculation of at least one individual product or individual sum, and/or is required for the propagation of the individual product or the individual sum onto the product or the sum, being absent in the arithmetic unit or being connected there in such a way that it is capable of being selectively deactivated, completely or partially, for a running time of the arithmetic unit,
wherein the method comprises the following steps:
based on specific input data that are provided for processing by the ANN, ascertaining a configuration of the arithmetic unit that determines which of the arithmetic modules of the arithmetic unit are to be deactivated for the running time;
completely or partially deactivating selected arithmetic modules of the arithmetic unit corresponding to the ascertained configuration;
supplying the input data to the ANN for the processing with the selected arithmetic modules completely or partially deactivated.

24. The method as recited in claim 23, wherein a measure of the resilience of the ANN to changes in the input data are ascertained based on the input data, and the configuration of the arithmetic unit is ascertained based on the measure of the resilience.

25. The method as recited in claim 23, wherein the configuration of the arithmetic unit is retrieved based on the input data from a further artificial neural network.

26. A non-transitory machine-readable data carrier on which is stored a computer program for operating an artificial neural network (ANN) that is implemented with at least one arithmetic unit including:
a plurality of arithmetic modules, at least one of the arithmetic modules being provided to calculate individual products or individual sums of digits of the inputted numbers, the plurality of arithmetic modules being connected in an adder that is configured to calculate digits of the product or of the sum, from the individual products or from the individual sums, at least one arithmetic module that is required for the calculation of at least one individual product or individual sum, and/or is required for the propagation of the individual product or the individual sum onto the product or the sum, being absent in the arithmetic unit or being connected there in such a way that it is capable of being selectively deactivated, completely or partially, for a running time of the arithmetic unit,
wherein the computer program, when executed by one or more computers, causing the one of more computers to perform the following steps:
based on specific input data that are provided for processing by the ANN, ascertaining a configuration of the arithmetic unit that determines which of the arithmetic modules of the arithmetic unit are to be deactivated for the running time;
completely or partially deactivating selected arithmetic modules of the arithmetic unit corresponding to the ascertained configuration;
supplying the input data to the ANN for the processing with the selected arithmetic modules completely or partially deactivated.

27. A computer configured to operate an artificial neural network (ANN) that is implemented with at least one arithmetic unit including:
a plurality of arithmetic modules, at least one of the arithmetic modules being provided to calculate individual products or individual sums of digits of the inputted numbers, the plurality of arithmetic modules being connected in an adder that is configured to calculate digits of the product or of the sum, from the individual products or from the individual sums, at least one arithmetic module that is required for the calculation of at least one individual product or individual sum, and/or is required for the propagation of the individual product or the individual sum onto the product or the sum, being absent in the arithmetic unit or being connected there in such a way that it is capable of being selectively deactivated, completely or partially, for a running time of the arithmetic unit,
the computer configured to:
based on specific input data that are provided for processing by the ANN, ascertain a configuration of the arithmetic unit that determines which of the arithmetic modules of the arithmetic unit are to be deactivated for the running time;
completely or partially deactivate selected arithmetic modules of the arithmetic unit corresponding to the ascertained configuration;
supply the input data to the ANN for the processing with the selected arithmetic modules completely or partially deactivated.
